(19) United States
(12) Patent Application Publication
(10) Pub. No.: US 2016/0067749 A1
(43) Pub. Date: Mar. 10, 2016

(54) ULTRASONIC CLEANING APPARATUS AND METHOD FOR CLEANING

(71) Applicant: SHIN-ETSU HANDOTAI CO., LTD., Tokyo (JP)

(72) Inventors: Hitoshi KABASAWA, Annaka (JP); Tatsuo ABE, Shirakawa (JP)

(21) Appl. No.: 14/783,356

(22) PCT Filed: Apr. 9, 2014
(86) PCT No.: PCT/JP2014/002032

§ 371 Date: Oct. 8, 2015

(30) Foreign Application Priority Data
May 14, 2013 (JP) 2013-102431

(51) Int. Cl. B08B 3/12; H01L 21/67; H01L 21/02

(52) U.S. Cl. CPC B08B 3/12; H01L 21/02052; H01L 21/67057

(57) ABSTRACT

The present invention is directed to a method for cleaning that performs ultrasonic cleaning of an object to be cleaned by using a cleaning tank having a bottom face with an inclination, the method for cleaning in which the object to be cleaned is cleaned by using a plurality of the cleaning tanks and making the cleaning tanks lying next to each other have bottom faces with inclinations in different directions. As a result, in cleaning of a wafer by ultrasonic cleaning, it is possible to eliminate cleaning nonuniformity of the wafer.

### TECHNICAL FIELD

The present invention relates to a method for cleaning and an ultrasonic cleaning apparatus, the method and the apparatus which clean an object to be cleaned such as semiconductor parts including a semiconductor wafer by immersing the object to be cleaned in a chemical solution or pure water and irradiating the object to be cleaned with ultrasonic waves.

### BACKGROUND ART

In cleaning of a semiconductor wafer, cleaning is usually performed in combination with ultrasonic cleaning in order to remove particles on a wafer front surface efficiently. In this ultrasonic cleaning, depending on the type of adhering particles, the state of a wafer, the quality after cleaning, and so forth, a frequency, an output, ultrasonic wave control, an ultrasonic cleaning tank, a cleaning time, and so forth are determined. Nowadays, ultrasonic cleaning by high-frequency waves of 1 MHz (so-called megasonic waves) is often performed to remove finer particles and prevent damage to the wafer front surface. However, the megasonic waves are high-frequency waves and therefore have high directivity, which causes a portion in a cleaning tank, the portion hidden behind a jig or the like, to be left without being cleaned and results in cleaning nonuniformity. To address this problem, a plurality of ultrasonic wave treatment tanks are placed and the position of a jig or the like is changed to eliminate cleaning nonuniformity.

Moreover, in the above-described ultrasonic cleaning, as an ultrasonic vibration plate, a stainless plate is mainly used. However, if the stainless plate is brought into direct contact with a cleaning liquid which is being used in cleaning, metal ions begin to dissolve therein from the stainless plate, and the metal ions contaminate the wafer or the cleaning tank. For this reason, a method adopting a double structure formed of a cleaning tank in which a cleaning liquid is put and an outer tank inside which a bottom face of the cleaning tank is placed, attaching an ultrasonic vibrator to the bottom face of the outer tank, putting propagation water for propagating ultrasonic waves, and indirectly irradiating, with ultrasonic waves, an object to be cleaned in the cleaning tank made of quartz glass or the like via the propagation water is used.

### CITATION LIST

### Patent Literature

Patent Document 1: Japanese Unexamined Patent publication (Kokai) No. H03-222419

Patent Document 2: Japanese Unexamined Patent publication (Kokai) No. 2007-44662

### SUMMARY OF INVENTION

### Technical Problem

In the propagation water in the outer tank, air bubbles are generated therein by the ultrasonic vibration propagating through the propagation water. Then, the air bubbles adhere to the bottom face of the cleaning tank and impair the propagation of the ultrasonic waves to the inside of the cleaning tank. To address this problem, a method of preventing the air bubbles adhering to the bottom face of the cleaning tank from remaining on the bottom face by inclining the bottom face of the cleaning tank and making the air bubbles move upward along the inclined face is disclosed (refer to Patent Documents 1 and 2).

However, as in an apparatus depicted in FIG. 2, for example, if a bottom face of a cleaning tank 1′ is inclined in such a way that the cleaning tank 1′ becomes deeper on the right side, ultrasonic waves (arrows) generated from a vibration plate 3′ attached to an outer tank 2′ are separated into ultrasonic waves passing through the bottom face of the cleaning tank 1′ and ultrasonic waves reflected off the bottom face of the cleaning tank 1′. The ultrasonic waves reflected off the bottom face of the cleaning tank 1′ propagate through propagation water 4′, are reflected off a bottom face of the outer tank 2′, and are separated again into ultrasonic waves passing through the bottom face of the cleaning tank 1′ and ultrasonic waves reflected off the bottom face of the cleaning tank 1′. As a result of those described above being repeatedly performed, the ultrasonic waves on the left side in the tank become more intense than the ultrasonic waves on the right side, resulting in variations in the intensity of the ultrasonic waves in the tank and eventually causing cleaning nonuniformity of a wafer W. In particular, when the wafer W is cleaned by an ultrasonic cleaning apparatus having two cleaning tanks (101a and 101b) depicted in FIG. 3, if the wafer W held by a holder faces in the same direction, variations in the intensity of the right and left ultrasonic waves become the same in all the tanks and significant cleaning nonuniformity is observed in the cleaned wafer W.

The present invention has been made in view of the above-described problem and an object thereof is to eliminate cleaning nonuniformity of a wafer in cleaning of a wafer by ultrasonic cleaning.

### Solution to Problem

To solve the above-described problem, the present invention provides a method for cleaning that performs ultrasonic cleaning of an object to be cleaned by using a cleaning tank having a bottom face with an inclination, the method for cleaning in which the object to be cleaned is cleaned by using a plurality of the cleaning tanks and making the cleaning tanks lying next to each other have bottom faces with inclinations in different directions.

With such a method for cleaning in which the cleaning tanks lying next to each other are made to have bottom faces with different inclinations, it is possible to make a location in which ultrasonic waves are intense and a location in which ultrasonic waves are weak in one cleaning tank different from a location in which ultrasonic waves are intense and a location in which ultrasonic waves are weak in the other cleaning tank, whereby a region with a high cleaning effect is complemented, making it possible to eliminate cleaning nonuniformity of an object to be cleaned, in particular, a wafer as a cleaning flow.

At this time, it is preferable that the directions of the inclinations of the bottom faces are made to be anterior-posterior symmetrical or left-right symmetrical between the cleaning tanks lying next to each other.

With the method for cleaning using such cleaning tanks, it is possible to eliminate cleaning nonuniformity more effectively.

Moreover, the present invention provides an ultrasonic cleaning apparatus including: a cleaning tank having a bottom face with an inclination; an outer tank inside which the bottom face of the cleaning tank is placed; and a vibration plate attached to the outer tank, the ultrasonic cleaning apparatus in which a plurality of the cleaning tanks are provided and the cleaning tanks lying next to each other have bottom faces with inclinations in different directions.

With such an ultrasonic cleaning apparatus including the cleaning tanks lying next to each other and having bottom faces with different inclinations, a location in which ultrasonic waves are intense and a location in which ultrasonic waves are weak in one cleaning tank are different from a location in which ultrasonic waves are intense and a location in which ultrasonic waves are weak in the other cleaning tank, whereby a region with a high cleaning effect is complemented, making it possible to eliminate cleaning nonuniformity of an object to be cleaned, in particular, a wafer.

In particular, it is preferable that, as the plurality of the cleaning tanks, cleaning tanks in which the directions of the inclinations of the bottom faces are anterior-posterior symmetrical or left-right symmetrical between the cleaning tanks lying next to each other are provided.

With the cleaning apparatus provided with such cleaning tanks, it is possible to eliminate cleaning nonuniformity more effectively.

### Advantageous Effects of Invention

By cleaning an object to be cleaned, in particular, a wafer by using the cleaning apparatus and the ultrasonic cleaning apparatus of the present invention, even when ultrasonic waves with directivity are used, a region with a high cleaning effect is complemented as a result of a location in which ultrasonic waves are intense and a location in which ultrasonic waves are weak in one cleaning tank being different from a location in which ultrasonic waves are intense and a location in which ultrasonic waves are weak in the other cleaning tank, which makes it possible to eliminate cleaning nonuniformity of the wafer as a cleaning flow. As a result, it is possible to clean the whole surface of the wafer uniformly.

### BRIEF DESCRIPTION OF DRAWINGS

FIG. 1 is a schematic diagram depicting an example (Example) of an ultrasonic cleaning apparatus of the present invention;

FIG. 2 is a schematic diagram depicting an example of one unit of a common ultrasonic cleaning apparatus;

FIG. 3 is a schematic diagram depicting an ultrasonic cleaning apparatus used in Comparative Example 1;

FIG. 4 is a schematic diagram depicting an ultrasonic cleaning apparatus used in Comparative Example 2;

FIG. 5 is a particle map of a wafer cleaned in Example;

FIG. 6 is a particle map of a wafer cleaned in Comparative Example 1; and

FIG. 7 is a particle map of a wafer cleaned in Comparative Example 2.

### DESCRIPTION OF EMBODIMENTS

Through an intensive study of a method for cleaning of cleaning an object to be cleaned by ultrasonic cleaning using a cleaning tank having an inclined bottom face, the inventors of the present invention have found out that a method for cleaning using a plurality of the above-described cleaning tanks and making the tanks lying next to each other have the bottom faces with different inclinations can complement a region with a high cleaning effect in the cleaning tank and eliminate cleaning nonuniformity of a wafer as a cleaning flow and completed the present invention.

Hereinafter, the present invention will be described with reference to the drawings.

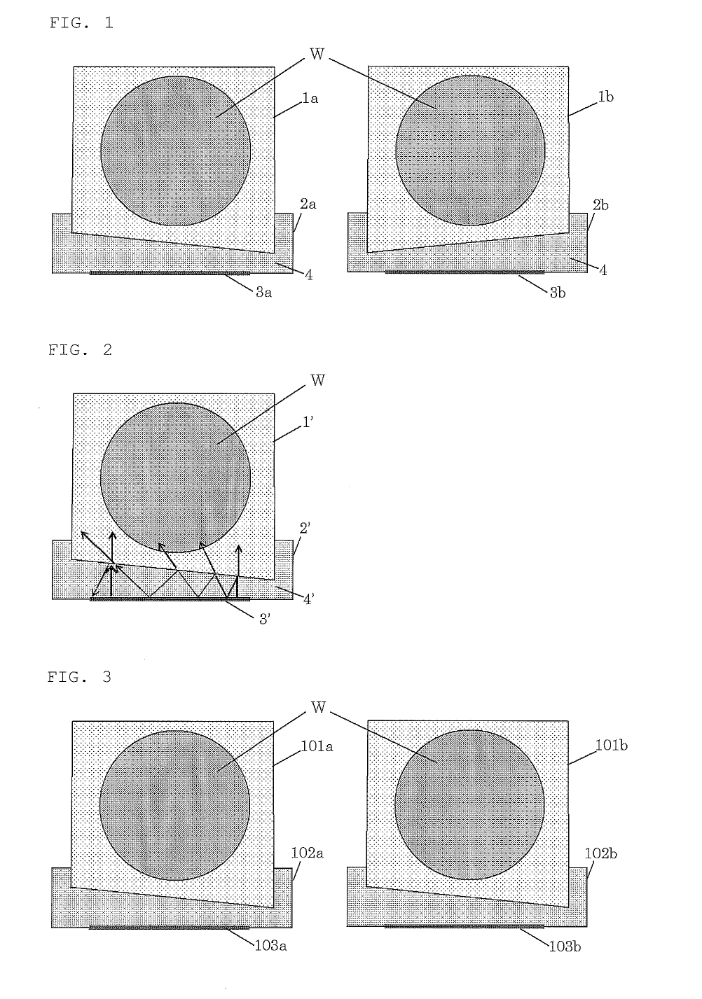

Examples of an apparatus that performs the above-described method can include an ultrasonic cleaning apparatus depicted in FIG. 1.

The ultrasonic cleaning apparatus depicted in FIG. 1 is obtained by placing, by using an apparatus depicted in FIG. 2 as one unit, two units in such a way that the bottom faces of cleaning tanks have different inclinations, includes cleaning tanks (1a and 1b), each having an inclined bottom face, outer tanks (2a and 2b) inside which the bottom faces of the cleaning tanks (1a and 1b) are placed, and vibration plates (3a and 3b) attached to the outer tanks (2a and 2b), and is obtained by placing two cleaning tanks (1a and 1b) in such a way that the bottom faces of the two cleaning tanks (1a and 1b) are inclined in opposite directions.

The cleaning tanks (1a and 1b) are filled with a cleaning liquid which will be described later and perform ultrasonic cleaning by immersing a wafer W in the cleaning liquid. The shape of such cleaning tanks (1a and 1b) is not limited to a particular shape as long as the cleaning tanks (1a and 1b) have inclined bottom faces and make air bubbles generated in propagation water 4 in the outer tanks (2a and 2b) move upward along the inclined bottom faces, and the side faces thereof may have a rectangular or cylindrical shape. Moreover, the material thereof is not limited to a particular material; for example, a cleaning tank made of quartz glass can be used.

The cleaning liquid which can be used in the present invention is not limited to a particular cleaning liquid; for example, any one of pure water, a mixed aqueous solution of ammonia water, hydrogen peroxide water, and pure water, a mixed aqueous solution of a tetramethylammonium aqueous solution and hydrogen peroxide water, and a mixed aqueous solution of caustic soda water and hydrogen peroxide water can be used. Such a cleaning liquid can be suitably used especially in cleaning of a polished silicon wafer or the like.

Moreover, the temperature of the cleaning liquid is not limited to a particular temperature and can be set appropriately. For example, in the case of a mixed aqueous solution of ammonia water, hydrogen peroxide water, and pure water, the temperature can be set at 30° C. or higher as a temperature that prevents an increase in surface roughness of a cleaned wafer while increasing the cleaning effect.

The bottom faces of the cleaning tanks (1a and 1b) are placed inside the outer tanks (2a and 2b) and the vibration plates (3a and 3b) are attached to the outer tanks (2a and 2b), and examples of the outer tanks (2a and 2b) can include an outer tank which is filled with the propagation water 4 to propagate ultrasonic waves. The ultrasonic cleaning apparatus described above cleans the wafer W via the cleaning tanks (1a and 1b), and, since there is no fear of contamination of the wafer by metal ions or the like caused by the outer tanks (2a and 2b), stainless steel can be adopted as the material of the outer tanks (2a and 2b).

The vibration plates (3a and 3b) can be formed as a vibration plate which is driven by application of a high-frequency voltage by an ultrasonic wave oscillator, for example. The type, material, shape, and so forth of such vibration plates (3a and 3b) are not limited to particular type, material, and shape; for example, a vibration plate similar to an existing vibration plate such as a piezoelectric vibrator can be adopted.

When the ultrasonic wave oscillator is used, the vibration plates (3a and 3b) can be made to oscillate by connecting the ultrasonic wave oscillator to each of the vibration plates (3a and 3b) and applying high-frequency waves thereto.

In the present invention, as the ultrasonic waves used for cleaning, high-frequency waves of 1 MHz or higher (so-called megasonic waves) can be adopted.

The above description has been given by using the ultrasonic cleaning apparatus depicted in FIG. 1; however, in the method for cleaning and the ultrasonic cleaning apparatus of the present invention, the ultrasonic cleaning apparatus may have three or more cleaning tanks depending on a desired cleaning level or the type of wafer, or an ultrasonic cleaning apparatus in which two or more units are placed in such a way that the bottom faces of cleaning tanks lying next to each other have different inclinations may be used.

In the present invention, the cleaning tanks lying next to each other are placed in such a way that the bottom faces thereof have different inclinations. As a result, it is possible to make one cleaning tank and the other cleaning tank have a location in which the ultrasonic waves are intense and a location in which the ultrasonic waves are weak, that is, variations in intensity, in different areas; therefore, even when a wafer which is cleaned by being held by a holder faces in the same direction, by performing successive immersion of the wafer, a region with a high cleaning effect is complemented, which makes it possible to eliminate cleaning nonuniformity of a wafer.

Furthermore, by making the bottom faces of the cleaning tanks lying next to each other have anterior-posterior symmetrical or left-right symmetrical inclinations, variations in intensity of the ultrasonic waves become symmetrical in the tanks lying next to each other, which makes it possible to eliminate cleaning nonuniformity more effectively and, as a result, clean the whole surface of the wafer uniformly.

### EXAMPLE

Hereinafter, the present invention will be described more specifically by using an example and comparative examples, but the present invention is not restricted thereto.

### Example

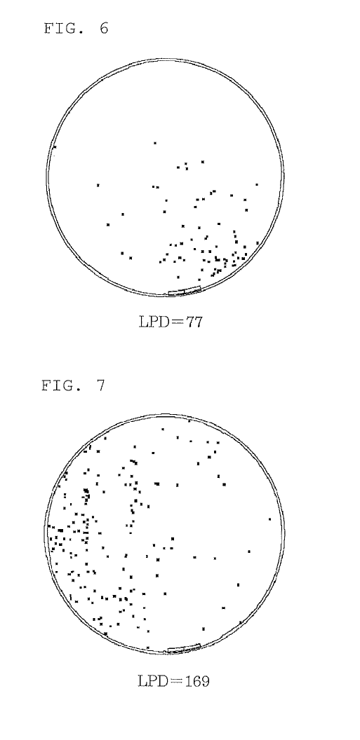

Ultrasonic cleaning by SC1 was performed on a silicon wafer W having a diameter of 300 mm, the silicon wafer W subjected to mirror polishing, by using two SC1 cleaning tanks (1a and 1b) for 6 minutes in total, 3 minutes in each tank, and rinsing in pure water and drying were then performed. An SC1 cleaning liquid used at this time was prepared by setting the mixture ratio of ammonia water (28 wt %), hydrogen peroxide water (30 wt %), and water at 1:1:10. Moreover, the temperature of the cleaning liquid was set at 50° C. As a first tank of the two cleaning tanks, a tank (1a) made of quartz glass and having a shape in which a bottom face is inclined in such a way that the tank becomes deeper on the right side was used, and, as a second tank, a tank (1b) made of quartz glass and having a shape in which a bottom face is inclined in such a way that the tank becomes deeper on the left side was used (FIG. 1). The number of particles (LPDs (Light Point Defects)) 37 nm) of the cleaned wafer was measured by a wafer front surface inspection apparatus (SP2 manufactured by KLA-Tencor Corporation). A particle map obtained by the measurement is depicted in FIG. 5. The number of LPDs is 24 and, as depicted in FIG. 5, the result reveals that the whole surface of the wafer was cleaned uniformly. Since the first tank has a shape in which the inclination of the bottom face of the cleaning tank becomes deeper on the right side, the effect of removing particles on the left side of the wafer is high; on the other hand, since the second tank has a shape in which the inclination of the bottom face of the cleaning tank becomes deeper on the left side, the effect of removing particles on the right side of the wafer can be increased. As a result, a region with a high cleaning effect by the ultrasonic waves can be complemented in the first tank and the second tank, which makes it possible to clean the whole surface of the wafer uniformly.

### Comparative Example 1

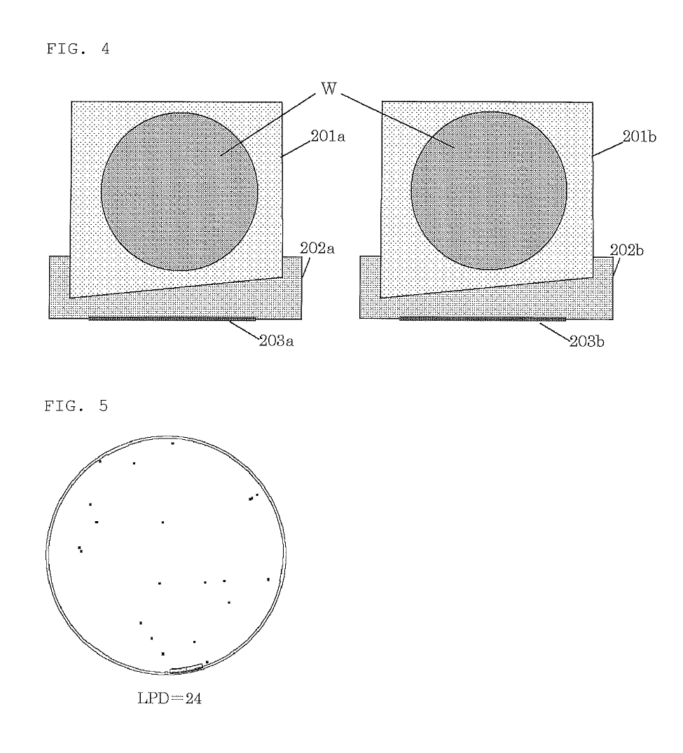

Cleaning was performed under the same conditions as those of Example 1 except that, as cleaning tanks, two tanks (101a and 101b), each having a shape in which a bottom face is inclined in such a way that the tank becomes deeper on the right side, were used (FIG. 3). A particle map obtained by the measurement is depicted in FIG. 6. The number of LPDs is 77 and, as depicted in FIG. 6, the result reveals that the particles remain unevenly on the right side of the wafer. Since the two tanks have a shape in which the inclination of the bottom face of the cleaning tank becomes deeper on the right side, as a result of part of the ultrasonic waves being reflected off the bottom face of the cleaning tank and the bottom face of the propagation tank (the outer tank) in the propagation tank, the ultrasonic waves on the left side of the cleaning tank become more intense. As a result, since the effect of the ultrasonic waves is enhanced also on the left side of the wafer in the cleaning tank as compared to the right side, although the particles on the left side of the wafer are removed, the particles on the right side remain without being removed.

### Comparative Example 2

Cleaning was performed under the same conditions as those of Example 1 except that, as cleaning tanks, two tanks (201a and 201b), each having a shape in which a bottom face is inclined in such a way that the tank becomes deeper on the left side, were used (FIG. 4). A particle map obtained by the measurement is depicted in FIG. 7. The number of LPDs is 169 and, as depicted in FIG. 7, the result reveals that the particles remain unevenly on the left side of the wafer. Since, in contrast with Comparative Example 1, the two tanks have a shape in which the inclination of the bottom face of the cleaning tank becomes deeper on the left side, as a result of part of the ultrasonic waves being reflected off the bottom face of the cleaning tank and the bottom face of the propagation tank (the outer tank) in the propagation tank, the ultrasonic waves on the right side of the cleaning tank become more intense. As a result, since the effect of the ultrasonic waves is enhanced also on the right side of the wafer in the cleaning tank as compared to the left side, although the particles on the right side of the wafer are removed, the particles on the left side remain without being removed.

The above results revealed that, with the method for cleaning and the ultrasonic cleaning apparatus of the present invention, it was possible to eliminate cleaning nonuniformity of a wafer as a result of a region with a high cleaning effect being complemented and obtain a wafer with the uniformly-cleaned whole surface.

It is to be understood that the present invention is not limited in any way by the embodiment thereof described above. The above embodiment is merely an example, and anything that has substantially the same structure as the technical idea recited in the claims of the present invention and that offers similar workings and benefits falls within the technical scope of the present invention.

1. A method for cleaning that performs ultrasonic cleaning of an object to be cleaned by using a cleaning tank having a bottom face with an inclination, wherein
the object to be cleaned is cleaned by using a plurality of the cleaning tanks and making the cleaning tanks lying next to each other have bottom faces with inclinations in different directions.

2. The method for cleaning according to claim 1, wherein
directions of the inclinations of the bottom faces are made to be anterior-posterior symmetrical or left-right symmetrical between the cleaning tanks lying next to each other.

3. An ultrasonic cleaning apparatus comprising:
a cleaning tank having a bottom face with an inclination;
an outer tank inside which the bottom face of the cleaning tank is placed; and
a vibration plate attached to the outer tank, wherein
a plurality of the cleaning tanks are provided, and
the cleaning tanks lying next to each other have bottom faces with inclinations in different directions.

4. The ultrasonic cleaning apparatus according to claim 3, wherein
the ultrasonic cleaning apparatus includes, as the cleaning tanks, cleaning tanks in which directions of the inclinations of the bottom faces are anterior-posterior symmetrical or left-right symmetrical between the cleaning tanks lying next to each other.
